(19) United States
(12) Patent Application Publication
(10) Pub. No.: US 2024/0091898 A1
(43) Pub. Date: Mar. 21, 2024

(54) WORK POLISHING APPARATUS AND WORK POLISHING METHOD

(71) Applicant: Fujikoshi Machinery Corp., Nagano (JP)

(72) Inventor: Yosuke KANAI, Nagano (JP)

(21) Appl. No.: 18/457,421

(22) Filed: Aug. 29, 2023

(30) Foreign Application Priority Data
Sep. 16, 2022 (JP) 2022-147494

(51) Int. Cl. B24B 7/10; B24B 51/00

(52) U.S. Cl. CPC B24B 7/10; B24B 51/00

(57) ABSTRACT

In a work polishing apparatus, a polishing head including a head base portion, in an upper portion, to which a vertically movable and rotatable head shaft is fixed, and a holding member, in a lower portion, having a lower surface on which a work is held, is provided with, on the upper surface side of the holding member, a vertically movable partitioning portion and first and second fluid chambers respectively on the inner and outer circumference sides of the partitioning portion. Pressure in the first fluid chamber and in the second fluid chamber can be independently increased or decreased. The partitioning portion can be lowered at least to a position where the first fluid chamber and the second fluid chamber are partitioned such that a pressure difference can be produced between the interior of the first fluid chamber and the interior of the second fluid chamber.

### CROSS-REFERENCE TO RELATED APPLICATION

This application is based upon and claims the benefit of priority of the prior Japanese Patent Application No. 2022-147494, filed on Sep. 16, 2022, and the entire contents of which are incorporated herein by reference.

### TECHNICAL FIELD

The present invention relates to a work polishing apparatus and a work polishing method.

### BACKGROUND ART

A known work polishing apparatus polishes a work through relative movement between a platen and a polishing head provided above the platen, in a state where the work is held on the lower surface of the polishing head and is pressed against a polishing pad attached on the upper surface of the platen (PTL 1: JP-A-2010-240767).

In the work polishing apparatus described as an example in PTL 1, the polishing head includes a head member forming an outer shape portion thereof and a holding plate vertically movably suspended from the head member via an elastic member, and has a fluid chamber defined between the head member and the holding plate. When a fluid is supplied into the fluid chamber and the pressure therein rises, the holding plate is pushed down. As a result, the work held on the lower surface side of the holding plate is pushed against the platen (polishing surface) to be polished.

### SUMMARY OF INVENTION

### Technical Problem

With the work polishing apparatus as described as an example in PTL 1 in which the work is pushed from the upper side by increasing the pressure in the fluid chamber, completely uniform pressing force is not necessarily applied over the entire region of the work. For example, the pressing force is generally likely to be unstable in a circumferential edge portion of the work compared with a center portion. Thus, to polish the work into a planer shape as a whole, a configuration is required that enables each predetermined region (for example, each of the center portion and circumferential edge portion) of the work to be pressed with a desired pressing force. Furthermore, the work before the polishing is also expected to have a difference in thickness between the vicinity of the center portion and the vicinity of the circumferential edge portion. Thus, there has not only been a demand for finishing the work to be flat as a whole by processing the entire surface of the work uniformly, but there has also been a demand for finishing the work to be flat as a whole through offsetting of the difference in thickness before the polishing or the like. To satisfy requirements related to such various polishing conditions, there has been a demand for a work polishing apparatus enabling each predetermined region of a work to be pressed with a desired pressing force, and the pressing force for each predetermined region to be easily changed.

### Solution to Problem

The present invention has been accomplished under the above circumstances, and an object of the present invention is to provide a work polishing apparatus and a work polishing method enabling each predetermined region of a work to be pressed with a desired pressing force, the pressing force to be easily changed, and the work to be polished into a desired thickness shape for an intended purpose.

The present invention achieves the object described above through the solutions described below as one embodiment.

A work polishing apparatus according to the present invention includes: a platen having an upper surface on which a polishing pad is attached, the platen rotating in a horizontal plane; and a polishing head that includes a head base portion in an upper portion and a holding member in a lower portion, in which a head shaft that is vertically movable and rotatable is fixed on an upper surface of the head base portion, a work is configured to be held on a lower surface of the holding member, and the work is configured to be lowered while rotating, via the head shaft, to be pressed onto the polishing pad on the upper surface of the platen rotating below to be polished, wherein the polishing head is provided with a first fluid chamber on side of an upper surface of the holding member, a second fluid chamber more on side of outer circumference than the first fluid chamber, and a partitioning portion that is vertically movable and is provided between the first fluid chamber and the second fluid chamber, a fluid is capable of being supplied into and discharged from each of the first fluid chamber and the second fluid chamber independently, pressure in the first fluid chamber and pressure in the second fluid chamber are each capable of being independently increased and decreased, and the partitioning portion is configured to be capable of being lowered at least to a position where the first fluid chamber and the second fluid chamber are partitioned in such a manner that a pressure difference is capable of being produced between the interior of the first fluid chamber and the interior of the second fluid chamber.

Thus, the partitioning portion is lowered, from the upper surface side of the holding member holding the work on its lower surface, to a position where a pressure difference can be produced between the first fluid chamber and the second fluid chamber respectively formed on the inner and the outer circumference sides, to partition both fluid chambers, whereby the internal pressure in each of the first fluid chamber and the second fluid chamber can be controlled. This enables control on pressure applied to each of a work region corresponding to the first fluid chamber, and one of a work region and an outer side region of the work or a region covering both of these regions, the regions corresponding to the second fluid chamber. Thus, each of the regions obtained by dividing a region including the work and the outer side region thereof in a radial direction can be pressed with a desired pressing force, which can be freely adjusted and easily changed. As a result, the work can be polished into a desired thickness shape for an intended purpose.

A vertical movement mechanism for the partitioning portion is not limited. In one example, the partitioning portion may be configured to be coupled to the head base portion and vertically move together with the head base portion vertically moving via the head shaft. In another example, the partitioning portion may be configured to be vertically movably suspended from the head base portion, and a third fluid chamber into and from which the fluid is capable of being supplied and discharged may be further provided above the partitioning portion, and the partitioning portion may be configured to vertically move in response to an increase or decrease in pressure in the third fluid chamber.

The partitioning portion is preferably a pressing mechanism portion capable of pressing a region, in a region including the work and an outer side region of the work, corresponding to a lower surface of the partitioning portion, via the holding member, by being lowered to press the holding member. Thus, the pressing mechanism portion serving as the partitioning portion can be lowered to press the sheet body, whereby a work region, the outer side region of the work, or a region covering both of these regions, the regions corresponding to the lower surface of the pressing mechanism portion, can be pressed via the holding member. The pressing force applied to the pressing region can be controlled by controlling the pressing force of the pressing mechanism portion. With the configuration where the pressing mechanism portion serves as the partitioning portion, each of the regions obtained by more finely dividing the region including the work and the outer side region of the work can be pressed with a desired pressing force that can be easily changed, and the work can be polished into a desired thickness shape for an intended purpose.

A pressing member is preferably detachably attached to a lower surface of the pressing mechanism portion or in a region of the upper surface of the holding member corresponding to the lower surface of the pressing mechanism portion. Thus, the pressing region of the pressing mechanism portion can be freely set and easily changed. Thus, each pressing region on the inner and the outer circumference sides of the pressing mechanism portion (pressing member) can be freely set and easily changed accordingly.

The pressing member is preferably detachably attached to the lower surface of the pressing mechanism portion via an attachment. Thus, the pressing member can be more easily attached and detached, and the pressing force of the pressing mechanism portion can be more uniformly transmitted over the entirety of the pressing member, so that the pressing can be more accurately performed as being set.

In one example, the polishing head may be configured as follows. Specifically, in the polishing head, the head base portion includes a base top plate having the head shaft fixed to an upper surface center portion, and a shaft portion protruding in a lower surface center portion of the base top plate, a work guide is positioned below the head base portion to be vertically movable with respect to the head base portion via a first suspending member, the partitioning portion is positioned below the work guide, is vertically movably suspended from the work guide via a second suspending member on outer circumference side, and is coupled to the shaft portion or is suspended via a third suspending member on inner circumference side, a holding plate is provided to a lower end of the shaft portion, the holding member is a sheet body that is provided to be positioned below the holding plate and has a circumferential edge portion fixed to the work guide, the first fluid chamber is formed between an upper surface of the sheet body and a lower surface of the holding plate on the inner circumference side of the partitioning portion, and the second fluid chamber is formed between an outer circumference surface of the partitioning portion and an inner circumference surface of the work guide on the outer circumference side of the partitioning portion.

A work polishing method according to the present invention is a work polishing method of polishing, into a set thickness shape, a work held on a lower surface of a holding member provided in a lower portion of a polishing head, by rotating and lowering the polishing head, and pressing, from above, the work onto a polishing pad attached to an upper surface of a platen rotating, with a pressing mechanism portion that is vertically movable and capable of being lowered to press the holding member provided on side of an upper surface of the holding member, and with a first fluid chamber and a second fluid chamber respectively provided on inner circumference side and outer circumference side of the pressing mechanism, the work polishing method including: controlling pressure in the first fluid chamber to control pressure applied to a relatively center portion side region of the work or to an entire region of the work, the regions corresponding to the first fluid chamber; controlling pressure in the second fluid chamber to control pressure applied to a relatively circumferential edge portion side region of the work, to an outer side region of the work, or to a region covering both of the relatively circumferential edge portion side region of the work and the outer side region of the work, the regions corresponding to the second fluid chamber; and controlling pressing force of the pressing mechanism portion to control pressing force applied to a region corresponding to a lower surface of the pressing mechanism portion positioned between a pressure control region controlled under the first fluid chamber and a pressure control region controlled under the second fluid chamber.

Thus, the pressures applied to the relatively center portion side region of the work or the entire region of the work, the regions corresponding to the pressure control region controlled under the first fluid chamber, the relatively circumferential edge portion side region of the work, the outer side region of the work, or the region covering both of these regions, the regions corresponding to the pressure control region controlled under the second fluid chamber, and the region that is positioned between these regions and is a region of the work, the outer side region of the work, or the region covering both of these regions, the regions corresponding to the pressing force control region of the pressing mechanism portion, can each be independently controlled. As a result, the work can be polished into a desired thickness shape for an intended purpose.

### Advantageous Effects of Invention

According to the present invention, each predetermined region of a work can be pressed with a desired pressing force, and the pressing force for each predetermined region can be easily changed. As a result, the work can be polished into a desired thickness shape for an intended purpose.

### BRIEF DESCRIPTION OF DRAWINGS

FIG. 1 is a schematic view (front cross-sectional view) illustrating an example of a polishing head of a work polishing apparatus according to an embodiment of the present invention.

FIG. 2 is a schematic view (front cross-sectional view) illustrating another example of the polishing head of the work polishing apparatus according to the embodiment of the present invention.

FIG. 3 is a schematic view (front cross-sectional view) illustrating an example of a driving unit of the polishing head illustrated in FIG. 1.

FIG. 4 is an explanatory view illustrating an arrangement of the polishing head and a platen illustrated in FIG. 1, and is a schematic view (plan view) illustrating an example of the work polishing apparatus according to the embodiment of the present invention.

FIG. 5 is a schematic view (front cross-sectional view) illustrating an example of a polishing head of a work polishing apparatus according to another embodiment of the present invention that is applicable to a work polishing method according to the embodiment of the present invention.

FIGS. 6A-6D are photographs illustrating a load distribution of a work pressed with the work polishing apparatus according to the present embodiment applied to the work polishing method according to the embodiment.

FIG. 7 is a graph illustrating a polishing amount of a work pressed with the work polishing apparatus according to the present embodiment applied to the work polishing method according to the embodiment.

### DESCRIPTION OF EMBODIMENTS

(Work Polishing Apparatus)

An embodiment of the present invention will be described in detail below with reference to the drawings. A work polishing apparatus 10 according to the present embodiment polishes a flat-plate shaped (disk shaped in particular) work W such as a wafer (silicon wafer for example) through relative movement between a polishing head 12 and a platen 14 performed with the polishing head 12 holding and pressing the work W against the platen 14.

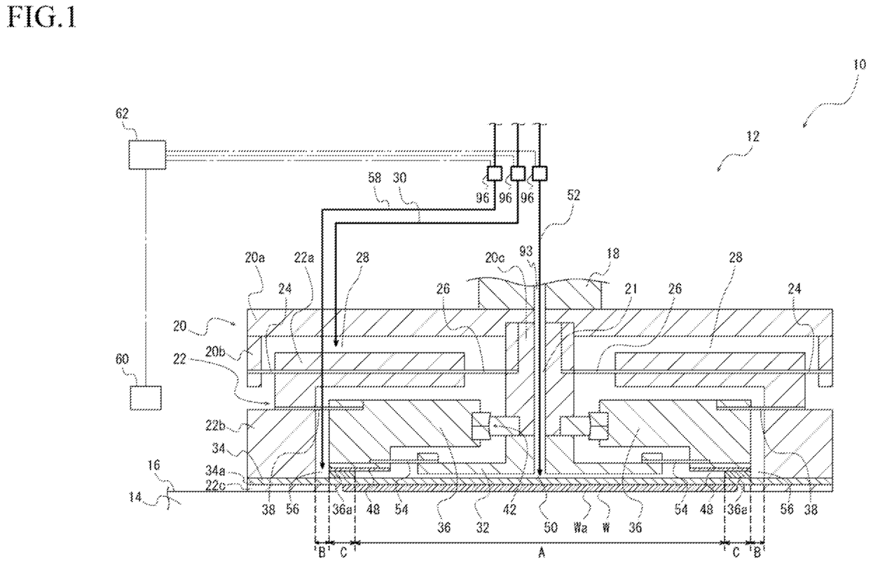

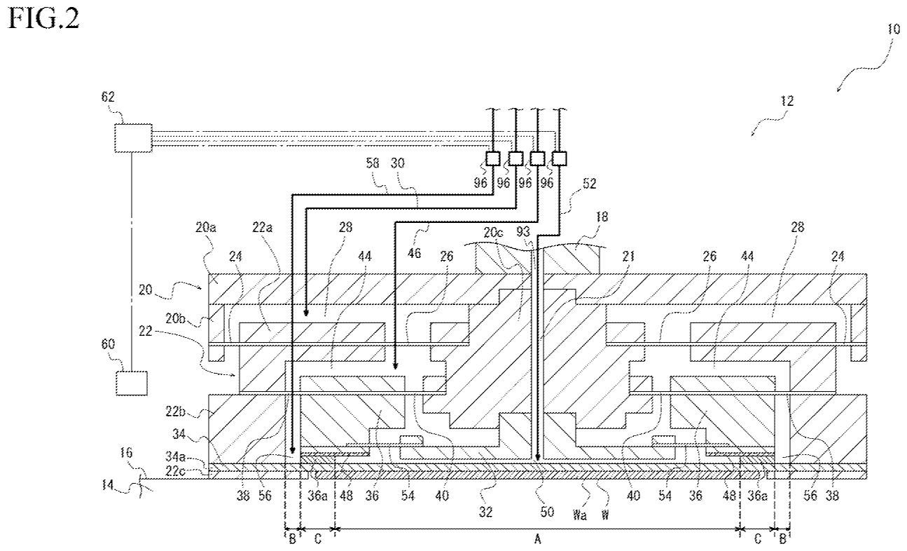

FIG. 1 is a schematic view (front cross-sectional view) illustrating an example of the polishing head 12 according to the present embodiment. FIG. 2 is a schematic view (front cross-sectional view) illustrating another example of the polishing head 12 according to the present embodiment. The polishing head 12 according to the present embodiment will be described below with reference to FIG. 1. With reference to FIG. 2, only the configuration different from that in FIG. 1 will be described. In other words, members having the same functions of the configuration common to FIG. 1 are denoted by the same reference numerals, and the description thereof will be omitted to avoid cumbersomeness. As illustrated in FIG. 1, the polishing head 12 operates as follows. Specifically, the work W is horizontally held with a polished surface Wa facing downward, on the lower surface of the polishing head 12, and is pressed, while being rotated, against a polishing pad 16 on the upper surface of the platen 14 rotating in a horizontal plane, to polish the work W.

Reference numeral 20 denotes a head base portion 20 including a base top plate 20a, a ring-shaped side wall portion 20b extending downward from the outer edge portion of the base top plate 20a, and a shaft portion 20c protruding downward from the center portion of the lower surface of the base top plate 20a. A head shaft 18 extending upward is fixed to the center portion of the upper surface of the head base portion 20. The head shaft 18 is rotated about an axis by a driving unit 64 described below. Thus, the head base portion 20 rotates together with the head shaft 18, about the head shaft 18. The head shaft 18 is vertically moved by the driving unit 64 described below. Thus, the head base portion 20 vertically moves together with the head shaft 18.

A work guide 22 is provided that is positioned below the head base portion 20, and includes a guide top plate 22a, a pressing ring portion 22b extending downward from the outer edge portion of the guide top plate 22a, and a retainer ring 22c provided on the lower surface of the pressing ring portion 22b. At the time of polishing the work W, the work guide 22 operates to hold the work W on the lower surface of a sheet body 34 described below, by pressing the polishing pad 16 in an outer side region of the work W while surrounding the work W with the retainer ring 22c.

The work guide 22 (guide top plate 22a) is suspended from the side wall portion 20b of the head base portion 20 via a first suspending member 24 on the outer circumference side, and is suspended on the outer circumference of the shaft portion 20c of the head base portion 20 via a fourth suspending member 26 on the inner circumference side. It is a matter of course that the first suspending member 24 and the fourth suspending member 26, which may be integrally configured as illustrated in FIG. 1, may be separately configured (not illustrated).

As described above, the work guide 22 is suspended from the head base portion 20 via the first suspending member 24 and the fourth suspending member 26. According to the present embodiment, the first and the fourth suspending members 24 and 26 are each formed by a diaphragm made of a rubber material, and a change in shape of the first and the fourth suspending members 24 and 26 leads to the vertical movement of the work guide 22 with respect to the base portion 20. The work guide 22 is configured to rotate upon receiving rotational force of the head base portion 20 rotating, transmitted through the first and the fourth suspending members 24 and 26. The configuration and the material of the first and the fourth suspending members 24 and 26 are not limited as long as the work guide 22 can be vertically movably suspended as described above. Thus, the diaphragm should not be construed in a limiting sense, and a bellows and the like may be used for example. Furthermore, the rubber material should not be construed in a limiting sense, and a resin material, a metal material, and the like may be used.

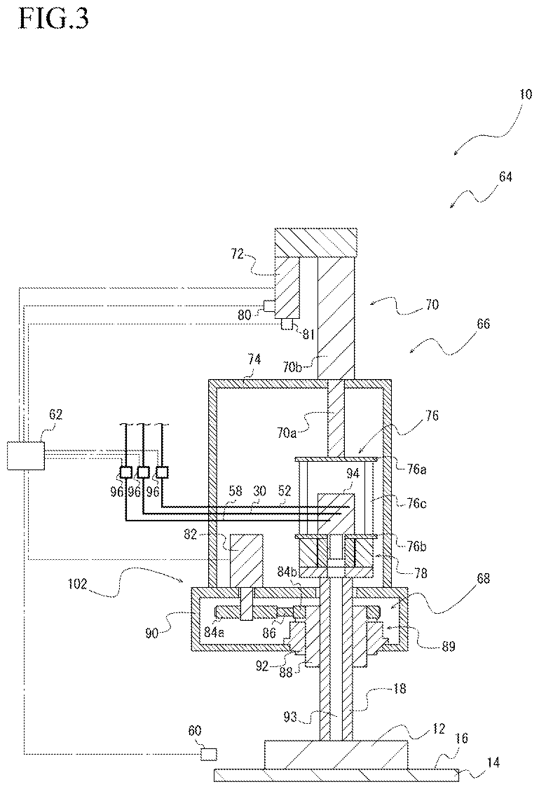

A fourth fluid chamber 28 is formed between the lower surface of the head base portion 20 (base top plate 20a) and the upper surface of the work guide 22 (and the first and the fourth suspending members 24 and 26). A fluid can be supplied into and discharged from the fourth fluid chamber 28 through a fourth flow path 30 provided with a pressure adjustment mechanism 96, so that the work guide 22 is pushed down when the internal pressure of the fourth fluid chamber 28 is of a positive value, and the work guide 22 is lifted up when the internal pressure of the fourth fluid chamber 28 is of a negative value. FIG. 1 and FIG. 3 illustrate a supply path of the fourth flow path 30 including the supply path and a discharge path. A plurality of the pressure adjustment mechanisms 96 may be provided, examples of which include a fluid compression device, a solenoid valve, and the like. This enables pressure force to be applied to the retainer ring 22c or to be reduced on the other hand for adjustment. Thus, at the time of polishing the work W, the retainer ring 22c presses the polishing pad 16 in the outer side region of the work W, so that side slipping (jumping out in a radial direction) of the work W rotating can be prevented. Furthermore, by adjusting the pressing force of the retainer ring 22c to press the polishing pad 16 in the outer side region of the work W to be substantially flush with a polished surface Wa of the work W, an edge portion of the work W (in particular, an outer edge portion in a circumferential edge portion of the work W) can be prevented from being excessively polished. Furthermore, the tension of the sheet body 34 described below can be changed to affect the polished shape of the work W.

In the configuration of the present embodiment, the fluid is air, and the air pressure in the fourth fluid chamber 28 is adjusted, but this configuration should not be construed in a limiting sense, and the fluid may be water, oil, or the like for example. While the fourth fluid chamber 28 is not an essential configuration of the present application, when the fourth fluid chamber 28 is provided, the first and the fourth suspending members 24 and 26 are configured to form a sealed space between the lower surface of the head base portion 20 and the upper surface of the work guide 22.

A holding plate 32 is fixed to the lower end of the shaft portion 20c. The sheet body 34 is positioned below the holding plate 32 (and a pressing mechanism portion 36 described below) and has a circumferential edge portion 34a fixed to the work guide 22 (lower surface of the pressing ring portion 22b). That is, the work guide 22 is configured to have the retainer ring 22c provided to the lower surface of the pressing ring portion 22b with the sheet body 34 provided in between. The sheet body 34 is an example of a holding member having a function of holding the work W as described in Claims. As described below, with the work W held on the lower surface of the sheet body 34, the work W is pressed while the work W is being polished, and is conveyed while the work W is not being polished. The sheet body 34 is formed using a flexible resin material such as polyethylene terephthalate (PET), a rubber material such as acrylonitrile Butadiene Rubber (NBR), and the like, but is not limited thereto.

The pressing mechanism portion 36 is disposed on the inner side of the work guide 22. The pressing mechanism portion 36 is an example of a partitioning portion as described in claims that is disposed on the upper surface side of the holding member (the sheet body 34 herein) and between a pressure adjustable fluid chamber (a first fluid chamber 50 described below herein) on the inner circumference side and a pressure adjustable fluid chamber (a second fluid chamber 56 described below herein) on the outer circumference side, and has a function of partitioning between the fluid chambers 50 and 56 by lowering at least to a position where a pressure difference can be produced between the fluid chambers 50 and 56.

The pressing mechanism portion 36 is positioned below the work guide 22, and is suspended from the work guide 22 via the second suspending member 38 on the outer circumference side, as illustrated in FIG. 1. The second suspending member 38 is formed by a diaphragm made of a rubber material, and can be changed in shape. The pressing mechanism portion 36 is coupled to the shaft portion 20c to be swingably supported thereby, on the inner circumference side. As an example of this swinging mechanism 42, a spherical surface bearing or the like is provided. This makes the pressing mechanism portion 36 operate to swing in the vertical direction in an arch shape about the shaft portion 20c, and thus vertically move relative to the work guide 22. As in the case of the first and the fourth suspending members 24 and 26, the configuration and the material of the second suspending member 38 are not particularly limited as long as the pressing mechanism portion 36 can be vertically movably suspended as described above.

According to the present embodiment, the pressing mechanism portion 36 operates as follows. Specifically, at the time of polishing the work W, the pressing mechanism portion 36 lowers together with the head base portion 20 to come into contact with the sheet body 34. Then, the pressing force from the head base portion 20 that is further lowered is transmitted through the shaft portion 20c, to mechanically press the work W and/or the outer side region of the work W (more specifically, a region, in a region including the work W and the outer side region of the work W, corresponding to the lower surface of the pressing mechanism portion 36) via the sheet body 34. In this process, the driving unit 64 described below adjusts the height position of the polishing head 12, so that the pressing force of the pressing mechanism portion 36 can be adjusted. The pressing mechanism portion 36 according to the present embodiment swings upon coming into contact with the work W and the polishing pad 16 in the outer side region of the work W via the sheet body 34, to have the pressing surface constantly maintained to be parallel with the work W and the polishing pad 16 in the outer side region of the work W. Thus, the work W and the outer side region of the work W can be pressed with uniform pressing force.

As another example, the pressing mechanism portion 36 may be configured to be suspended by the work guide 22 via the second suspending member 38 on the outer circumference side and via the third suspending member 40 on the inner circumference side as illustrated in FIG. 2. It is a matter of course that the second suspending member 38 and the third suspending member 40, which may be integrally configured as illustrated in FIG. 2, may be separately configured (not illustrated) instead. In this configuration, as in the case of the second suspending member 38, the third suspending member 40 is formed by a diaphragm made of a rubber material, and a change in shape of the second and the third suspending members 38 and 40 leads to the vertical movement of the pressing mechanism portion 36 relative to the work guide 22 and the base portion 20. The pressing mechanism portion 36 is configured to rotate upon receiving rotational force of the head base portion 20 rotating, transmitted through the second and the third suspending members 38 and 40. The configuration and the material of the third suspending member 40 are not limited as long as the pressing mechanism portion 36 can be vertically movably suspended as described above, as in the case of the second suspending member 38.

In this example, as illustrated in FIG. 2, a third fluid chamber 44 is formed between the lower surface of the work guide 22 (the guide top plate 22a) (and the fourth suspending member 26) and the upper surface of the pressing mechanism portion 36 (and the second and the third suspending members 38 and 40). A fluid can be supplied into and discharged from the third fluid chamber 44 through a third flow path 46 provided with a pressure adjustment mechanism 96, so that the pressing mechanism portion 36 can be vertically moved. Specifically, the pressing mechanism portion 36 is pushed down when the internal pressure of the third fluid chamber 44 is of a positive value, and the pressing mechanism portion 36 is lifted up when the internal pressure of the third fluid chamber 44 is of a negative value. FIG. 2 illustrates a supply path of the third flow path 46 including the supply path and a discharge path. A plurality of the pressure adjustment mechanisms 96 may be provided, examples of which include a fluid compression device, a solenoid valve, and the like. This enables pressure force to be applied to the pressing mechanism portion 36 or to be reduced on the other hand for adjustment. Thus, at the time of polishing the work W, the pressing mechanism portion 36 operates to press the work W and/or the outer side region of the work W (more specifically, a region, in a region including the work W and the outer side region of the work W, corresponding to the lower surface of the pressing mechanism portion 36) via the sheet body 34 with any appropriate pressing force using the pressure of the fluid. In the present example, the fluid is air, and the air pressure in the third fluid chamber 44 is adjusted, but this configuration should not be construed in a limiting sense, and the fluid may be water, oil, or the like for example. When the third fluid chamber 44 is provided as in the present example, the second, the third, and the fourth suspending members 26, 38, and 40 are configured to form a sealed space between the lower surface of the work guide 22 and the upper surface of the pressing mechanism portion 36.

Also in the present embodiment illustrated in FIG. 1, the third fluid chamber 44 in fluid communication with the third flow path 46 may be provided. In this case, the pressing mechanism portion 36 includes both of the mechanical pressing mechanism based on the vertical movement of the polishing head 12 and the pressing mechanism based on the fluid pressure in the third fluid chamber 44.

A pressing member 36a that has a predetermined longitudinal width (thickness) and a lateral width (inner/outer diameter) is detachably attached to the lower surface of the pressing mechanism portion 36 as illustrated in FIG. 1. The pressing member 36a is preferably formed in a ring shape, or may be formed by a plurality of split pieces obtained by radially splitting a ring member from its center. In the latter case, there may be gaps among the split pieces. When there are the gaps, the pressing member 36a may elastically deform upon being pressed against the sheet body 34 with a predetermined pressing force to be formed into a continuous ring shape with the gaps filled. Alternatively, some or all of the gaps may not be filled, and a certain gap may constantly exist. The longitudinal width and the lateral width (an attachment range in the lower surface of the pressing mechanism portion 36) and the arrangement (an attachment position in the lower surface of the pressing mechanism portion 36) of the pressing member 36a are not limited. With such a pressing member 36a, the pressing region of the pressing mechanism portion 36 can be freely set and easily changed. Conceptually, the pressing member 36a is recognized as part of the pressing mechanism portion 36.

For example, the pressing member 36a is formed by a material such as a rubber material that can be a cushioning material, and can also be formed by a resin material such as Teflon (registered trademark), a metal material such as stainless steel (SUS), or the like, but is not limited to these. Also through such material selection, the pressing force of the pressing mechanism portion 36 can be freely set and easily changed. The pressing member 36a is detachably attached to the lower surface of the pressing mechanism portion 36 via an attachment 48 as illustrated in FIG. 1. With the attachment 48, the pressing member 36a can be more easily attached and detached, and the pressing force of the pressing mechanism portion 36 can be more uniformly transmitted over the entirety of the pressing member 36a, so that the pressing can be more accurately performed as being set. More specifically, for example, the attachment 48 to which the pressing member 36a is attached is fixed to the pressing mechanism portion 36 by using bolts or the like. Thus, without detaching the pressing mechanism portion 36 from the polishing head 12, positioning as well as the attachment and the detachment can be easily implemented with respect to the pressing mechanism portion 36. Here, the pressing member 36a can be easily fixed to the attachment 48 in advance using an adhesive or the like for example. This means that the pressing member 36a does not need to be provided with a bolt hole or the like for example. Thus, the pressure applied is uniformly transmitted over the entirety of the pressing member 36a, whereby a corresponding region can be entirety pressed via the sheet body 34 accurately as being set with uniform pressure. Still, how the pressing member 36a and the attachment 48 are fixed is not limited. In one example, the pressing member 36a may be fixed to the attachment 48 using a bolt or the like. The attachment 48 may not be provided, and the pressing member 36a may be directly fixed to the lower surface of the pressing mechanism portion 36.

In another example, a configuration (not illustrated) may be employed in which the pressing member 36a is provided in a region of the upper surface of the sheet body 34 corresponding to the lower surface of the pressing mechanism portion 36. In this case, for example, the pressing member 36a may be fixed to the sheet body 34 by adhesion using a both-sided tape, an adhesive, or the like, and in other like ways.

As described above, in the polishing head 12 according to the present embodiment, the work W is held on the lower surface of the sheet body 34 serving as the holding member, and the vertically movable pressing mechanism portion 36 is provided on the side of the upper surface of the sheet body 34. Furthermore, on the side of the upper surface of the sheet body 34, the first fluid chamber 50 and the second fluid chamber 56 are respectively formed on the inner circumference side (inner wall side) and the outer circumference side (outer wall side) of the pressing mechanism portion 36 and are partitioned by the pressing mechanism portion 36. Thus, the pressing mechanism portion 36 according to the present embodiment serves as a partitioning portion that partitions the fluid chambers 50 and 56 respectively formed on the inner circumference side and the outer circumference side thereof, and is configured to be vertically movable. Thus, the level of separation between the fluid chambers 50 and 56 (for example, how much the internal pressures of the respective fluid chambers 50 and 56 affect each other, that is, the level of independence of respective internal pressure adjustment mechanisms for the fluid chambers 50 and 56, as described below) can be adjusted.

The first fluid chamber 50 is formed between the upper surface of the sheet body 34 and the lower surface of the holding plate 32 (and the lower surface of the pressing mechanism portion 36) as illustrated in FIG. 1. The fluid can be supplied into and discharged from the first fluid chamber 50 through a first flow path 52 provided with a pressure adjustment mechanism 96, so that the internal pressure of the first fluid chamber 50 can be of a positive value and a negative value. Furthermore, the first fluid chamber 50 can be opened to the outside of the polishing head 12 through the first flow path 52, or can be sealed. FIG. 1 and FIG. 3 illustrate a supply path in fluid communication with a pipe 21 provided in the shaft portion 20c for example, in the first flow path 52 including the supply path and a discharge path. A plurality of the pressure adjustment mechanisms 96 may be provided, examples of which include a fluid compression device, a solenoid valve, and the like.

With the interior of the first fluid chamber 50 set to be vacuum (negative pressure), the work W can be absorbed and held on the lower surface of the sheet body 34. Thus, the work W can be picked up. Furthermore, the work W can be mechanically pressed by the holding plate 32 via the sheet body 34, with the pressing force from the head base portion 20 lowered transmitted to the holding plate 32 via the shaft portion 20c. On the other hand, by setting the internal pressure of the first fluid chamber 50 to be a positive value, the work W can be pressed via the sheet body 34 using the pressure of the fluid. The polished surface Wa of the work W can be polished by pressing the work W with these mechanisms, by supplying slurry to the work W, and by bringing the polishing pad 16 and the work W into sliding contact with each other while rotating the platen 14 and the polishing head 12. By controlling the internal pressure of the first fluid chamber 50 and controlling the height position of the polishing head 12 (holding plate 32), the pressing force for the work W can be adjusted, whereby the polished shape of the work W can be affected.

In the present embodiment, the fluid is air, and the air pressure in the first fluid chamber 50 is adjusted, but this configuration should not be construed in a limiting sense, and the fluid may be water, oil, or the like for example. As illustrated in FIG. 1, the first fluid chamber 50 may be formed with the holding plate 32 and the pressing mechanism portion 36 coupled to each other at a predetermined position through the fifth suspending member 54 and the like. Thus, the first fluid chamber 50 can be limited to an appropriate size, whereby the pressure therein can be more accurately adjusted. The first fluid chamber 50 is limited to be a predetermined region formed between the upper surface of the sheet body 34 and the lower surface of the holding plate 32, so that the pressure of the fluid can be affected to the sheet body 34 without waste. Still, limiting the defined first fluid chamber 50 to a predetermined size and position using the fifth suspending member 54 and the like is not an essential feature. While the fifth suspending member 54 is formed of a diaphragm made of a rubber material, the configuration and the material thereof are not limited, as in the case of the first, the second, the third, and the fourth suspending members 24, 26, 38, and 40.

The second fluid chamber 56 is formed between the outer circumference surface of the pressing mechanism portion 36 and the inner circumference surface of the work guide 22 (pressing ring portion 22b) as illustrated in FIG. 1. A fluid can be supplied into and discharged from the second fluid chamber 56 through a second flow path 58 provided with a pressure adjustment mechanism 96. Thus, the internal pressure of the second fluid chamber 56 can be set to be a positive value or a negative value. Furthermore, the second fluid chamber 56 can be opened to the outside of the polishing head 12 through the second flow path 58, or can be sealed. FIG. 1 and FIG. 3 illustrate a supply path of the second flow path 58 including the supply path and a discharge path. A plurality of the pressure adjustment mechanisms 96 may be provided, examples of which include a fluid compression device, a solenoid valve, and the like.

By setting the internal pressure of the second fluid chamber 56 to be a positive value, the work W and/or the outer side region of the work W can be pressed via the sheet body 34 by the pressure of the fluid. On the other hand, by setting the internal pressure of the second fluid chamber 56 to be a negative value, a predetermined suction force can be applied to the work W and/or the outer side region of the work W via the sheet body 34 to reduce the load. By controlling the internal pressure of the second fluid chamber 56, the pressing force to the work W and/or the outer side region of the work W can be adjusted, and the polished shape of the work W can be affected. In the present embodiment, the fluid is air, and the air pressure in the second fluid chamber 56 is adjusted, but this configuration should not be construed in a limiting sense, and the fluid may be water, oil, or the like for example.

As described above, in the present embodiment, the pressing mechanism portion 36 is lowered, from the upper surface side of the sheet body 34 extending over the entire work W and the outer side region of the work W, to a position where a pressure difference can be produced between the first fluid chamber 50 and the second fluid chamber 56 respectively formed on the inner and the outer circumference sides, to partition both fluid chambers 50 and 56, whereby the internal pressure in each of the first fluid chamber 50 and the second fluid chamber 56 can be controlled. This enables control on pressure applied to each of a relatively center portion side region of the work W and the entire region of the work W (region indicated by an arrow A), the regions corresponding to the first fluid chamber 50, and one of a relatively circumferential edge portion side region of the work W and the outer side region of the work W or a region (region indicated by an arrow B) covering both of these regions, the regions corresponding to the second fluid chamber 56, as illustrated in FIG. 1. Thus, each of the regions, obtained by dividing a region including the work W and the outer side region thereof in a radial direction, into a center portion side region of the work W and a circumferential edge portion side region for example, can be pressed with a desired pressing force, which can be easily changed. As a result, the work W can be polished into a desired thickness shape for an intended purpose.

According to the present embodiment, the partitioning portion (pressing mechanism portion 36) can be further lowered to press the sheet body 34 using the mechanical pressing mechanism based on the vertical movement of the polishing head 12 or (and) the pressing mechanism based on the pressure of the fluid in the third fluid chamber 44, whereby the region of the work W, the outer side region of the work W, or a region (region indicated by an arrow C) covering both of these regions, the regions corresponding to the lower surface of the partitioning portion (pressing mechanism portion 36), can be pressed via the sheet body 34 as illustrated in FIG. 1. The pressing force applied to the pressing region can be controlled by controlling the pressing force of the pressing mechanism portion 36 based on the height position of the pressing mechanism portion 36 or (and) the internal pressure of the third fluid chamber 44. With the configuration according to the present embodiment where the pressing mechanism portion 36 serves as the partitioning portion, each of the regions obtained by more finely dividing the region including the work W and the outer side region of the work W can be pressed with a desired pressing force that can be easily changed.

Furthermore, the pressing force for the region corresponding to the first and the second fluid chambers 50 and 56 can also be changed in various ways, by adjusting the level of separation between the fluid chambers 50 and 56 through a vertical movement of the partitioning portion (pressing mechanism portion 36). For example, the partitioning may be implemented to cause no fluid communication between the first fluid chamber 50 and the second fluid chamber 56, with the pressing force of the pressing mechanism portion 36 set to be relatively strong. Thus, the internal pressure of each of the fluid chambers 50 and 56 is highly accurately controlled with a corresponding one of the pressure adjustment mechanisms 96, so that the corresponding region can be pressed with a highly accurate pressing force. On the other hand, a gap may be provided between the first fluid chamber 50 and the second fluid chamber 56, with the pressing force of the pressing mechanism portion 36 set to be relatively small. Thus, a predetermined amount of fluid flows from one of the fluid chambers to the other to produce a change in pressure difference between the first and the second fluid chambers 50 and 56, so that a predetermined change can be made on the polished shape. The pressing mechanism portion 36 can be completely separated from the sheet body 34, resulting in communication between the first fluid chamber 50 and the second fluid chamber 56. Thus, the first and the second fluid chambers 50 and 56 as a whole can be formed as one fluid chamber, the internal pressure thereof being adjustable to be uniform through one of the flow paths (for example, the first flow path 52). In this case, when the work W has a relatively small size for example, the work W as a whole (as well as the outer side region thereof) can be uniformly pressed with constant pressing force, to be polished into a flat shape.

For example, the pressure of the first fluid chamber 50 may be used as a reference, and the internal pressure of the second fluid chamber 56 may be set to be higher than that of the first fluid chamber 50, so that the pressing force for the region on the circumferential edge portion side of the work W can be made larger than that for the region on the center portion side. Alternatively, the internal pressure of the second fluid chamber 56 may be set to be lower than that of the first fluid chamber 50, so that the pressing force for the region on the circumferential edge portion side of the work W can be made smaller than that for the region on the center portion side. Furthermore, only the circumferential edge portion of the work W or the outer side region of the work W may be pressed, with the internal pressure of the first fluid chamber 50 set to be a negative value or the first flow path 52 (for example, the discharge path) opened (that is, the first fluid chamber 50 is placed in an open-to-atmosphere state in the present embodiment) while the internal pressure of the second fluid chamber 56 is set to be a positive value to adjust pressure. As illustrated in this example, the pressing force applied to each of the regions from the center portion of the work W to the outer side region of the work W can be adjusted in any appropriate manner, by combining the positive pressure, the negative pressure, open, and sealed states in the first fluid chamber 50 and the second fluid chamber 56.

With the partitioning portion (pressing mechanism portion 36) according to the present embodiment, the detachably attached pressing member 36a enables the pressing region of the pressing mechanism portion 36 to be freely set and easily changed. Thus, each pressure control region on the inner and the outer circumference sides of the pressing mechanism portion 36 (pressing member 36a) can be freely set and easily changed accordingly. As a result, the work W can be polished into a desired thickness shape for an intended purpose.

For example, as illustrated in FIG. 1, a configuration may be employed in which the pressing region (referred to as “region c”) of the pressing mechanism portion 36 is defined as a region covering the circumferential edge portion of the work W and the outer side region of the work W (in particular, the outer circumference portion of the work W), the pressure control region (referred to as “region b”) controlled under the second fluid chamber 56 on the outer circumference side of the region c is defined as a further outer side region of the work W (in particular, a region corresponding to an inner edge portion of the retainer ring 22c), and the pressure control region (referred to as “region a”) controlled under the first fluid chamber 50 on the inner circumference side of the region c is defined as a center portion of the work W. For example, the region c may be shifted to be more on the inner circumference side, and the region b may be the region covering the circumferential edge portion (in particular, the outer edge portion) of the work W and the outer side region of the work W. On the other hand, the region c may be conversely shifted to be more on the outer circumference side to be the outer side region of the work W (in particular, the outer circumference portion of the work W), and the region b may be the further outer side region of the work W (in particular, the region corresponding to the inner edge portion of the retainer ring 22c), and the region a may be the entire region of the work W.

Next, the driving unit 64 of the polishing head 12 will be described. FIG. 3 is a schematic view (front cross-sectional view) illustrating an example of the driving unit 64. The driving unit 64 operates to vertically move and rotate the head shaft 18 to vertical move and rotate the polishing head 12. The driving unit 64 includes a vertical movement driving mechanism 66 and a rotational driving mechanism 68.

As illustrated in FIG. 3, the vertical movement driving mechanism 66 includes a driving source 72 that is drivingly controlled by the control unit 62 and a linear movement device 70 driven by the driving source 72. In the present embodiment, the driving source 72 is configured as a servomotor 72, and the linear movement device 70 is configured as a ball screw spline mechanism 70. The ball screw spline mechanism 70 is configured as follows. Specifically, the upper end of a spline shaft 70a to be in spline engagement with a spline outer tube portion 70b is screwed to a ball screw shaft (not illustrated). When the ball screw shaft is driven by the servomotor 72 via a timing belt or a gear mechanism (not illustrated), the spline shaft 70a is driven in the vertical direction. The spline outer tube portion 70b is fixed to a base frame 74. The lower end of the spline shaft 70a is fixed to a transmission frame 76 coupling between upper and lower support plates 76a and 76b with a shaft 76c. The upper end of the head shaft 18 is coupled to the lower support plate 76b via a coupling portion 78, to be rotatable about an axis.

As illustrated in FIG. 3, a current detector 80 that detects a value of current flowing in the servomotor 72 and/or an encoder 81 that detects the rotation speed or the rotation angle of the servomotor 72 may be provided. For example, these may be connected to the control unit 62, and the control unit 62 may control the torque of the servomotor 72 based on these pieces of information (detection values). The current detector 80 detects the value of the current flowing in the servomotor 72, so that the load applied to the work W when the work W is pressed by the pressing mechanism portion 36 and the holding plate 32 via the sheet body 34 can be recognized. With the encoder 81, the height position of the polishing head 12 can be directly detected, based on the rotation speed or the rotation angle of the servomotor 72. Thus, for example, by drivingly controlling the servomotor 72 to regulate the detection value from these to a predetermined value or range, the work W can be prevented from receiving excessive pressing force.

As illustrated in FIG. 3, the rotational driving mechanism 68 includes a driving source 82 drivingly controlled by the control unit 62, and rotates the head shaft 18. In the present embodiment, the driving source 82 is configured as a servomotor 82, and a rotating portion 88 is provided that is rotated via a first pulley 84a, a belt 86, and a second pulley 84b, or via a gear mechanism (not illustrated). The rotating portion 88 and the head shaft 18 are in spline engagement to enable the vertical movement of the head shaft 18, while the rotation of the rotating portion 88 is transmitted to the head shaft 18 to be rotated about an axis. Thus, in the present embodiment, the rotating portion 88 is configured as a spline outer tube portion 88 of a rotary ball spline mechanism 89 that also serves as a guide mechanism of the linear movement device 70, and the head shaft 18 configured as a spline shaft 18 is configured to vertical move and rotate. The rotary ball spline mechanism 89 includes the spline outer tube portion 88 and a flange portion 92 that rotatably supports the spline outer tube portion 88, and is fixed to a support box 90 via the flange portion 92. The servomotor 82 is also fixed to the support box 90.

The configuration of the vertical movement driving mechanism 66 and the rotational driving mechanism 68 is not limited, and may be any configuration that vertically moves and rotates the head shaft 18. For example, as the vertical movement driving mechanism 66, a linear motor or the like obtained by integrating the driving source 72 and the linear movement device 70 may be used. Furthermore, a linear motor actuator or the like obtained by further integrating a guide mechanism of the linear movement device 70 may be used. In this case, a spindle or the like may be used as the rotational driving mechanism 68 and directly rotate the head shaft 18. Alternatively, a linear motor actuator or the like incorporating the rotational driving mechanism 68 may be used (none of these are illustrated). As a modification of the present embodiment, the spline shafts 70a and 18 may be similarly configured by the ball screw spline mechanism 70 and the rotary ball spline mechanism 89. With a configuration in which a linear slide or the like is provided as the guide mechanism of the linear movement device 70 instead of the rotary ball spline mechanism 89 and a spindle or the like is provided as the rotational driving mechanism 68, the guide mechanism and the rotational driving mechanism 68 may be separately configured (none of these are illustrated). Still, with the vertical movement driving mechanism 66 including the spline mechanisms 70 and 89 (including the ball spline mechanism and the rotary ball spline mechanism) as in the present embodiment, the head shaft 18 can be highly accurately placed at a precise height position.

As illustrated in FIG. 1 and FIG. 3, the first, the second, and the fourth flow paths 30, 52, and 58 (supply paths) are in fluid communication with the pipe 93 provided in the head shaft 18 via a rotary joint 94, to communicate with the first, the second, and the fourth fluid chambers 28, 50, and 56 (the third flow path 46 provided as illustrated in FIG. 2, may be similarly formed). In FIG. 1, for the sake of visibility, the second and the fourth flow paths 30 and 58, other than the first flow path 52, are indicated by arrows leading directly to the second and the fourth fluid chambers 28 and 56 from the outside of the polishing head 12, without passing through the pipe 93. The pressure adjustment mechanism 96 is connected to the control unit 62, and the internal pressure of each of the fluid chambers 28, 50, and 56 can be adjusted through the control by the control unit 62 (the third fluid chamber 44 provided as illustrated in FIG. 2, may be similarly formed).

A sensor 60 that detects the height position of the polishing head 12 may be provided outside the polishing head 12. For example, the sensor 60 may be provided with a length measurement sensor or the like that detects the distance between the head base portion 20 and the work guide 22 in the vertical direction, the distance between the head base portion 20 and the polishing pad 16 in the vertical direction, or the like. The sensor 60 may be connected to the control unit 62, and the control unit 62 may be configured to control the head shaft 18, that is, the height position of the polishing head 12 via a servo mechanism in accordance with information (detection value) from the sensor 60. With this configuration, by detecting the height position of the polishing head 12 at a position extremely close to the work W, which is the polishing target, an impact of an dimensional error, an assembly error, and the like of the polishing head 12 and each member related to the vertical movement driving mechanism 66 can be reduced as much as possible. By vertically moving the head shaft 18 based on the information (detection value) of the sensor 60, the polishing head 12 can be highly accurately placed at a predetermined precise height position. As a result, the pressing force of the pressing mechanism portion 36 can be highly accurately controlled.

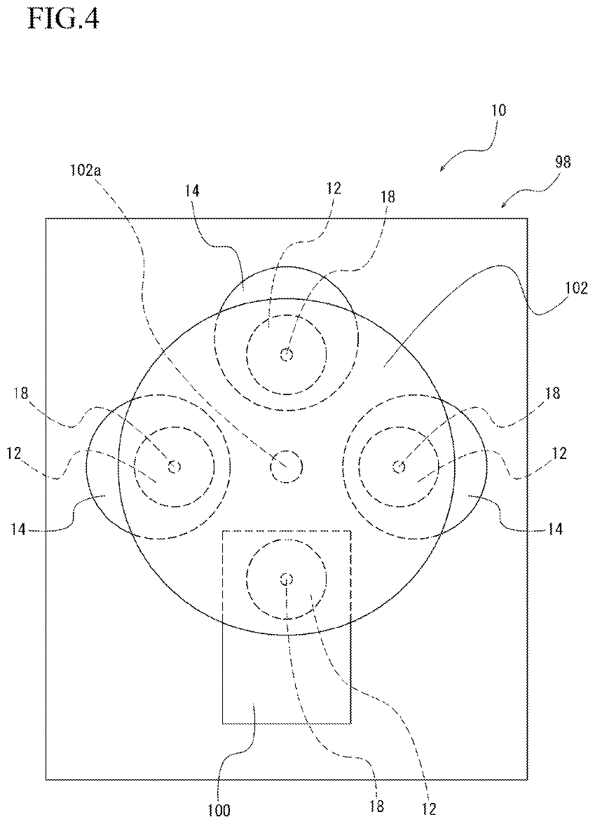

The platen 14 is formed in a disk shape in plan view (see FIG. 4), and has the polishing pad 16 attached to the upper surface (see FIG. 1). The platen 14 is provided with a rotational driving mechanism (not illustrated), and configured to be rotatable about an axis in a horizontal plane. Furthermore, a slurry supply unit (not illustrated) that supplies the slurry for the polishing is provided over the polishing pad 16. Thus, at the time of polishing the work W, while the slurry is being supplied to the work W, the polishing head 12 and the platen 14 rotating relative to each other make relative motions so that the work W and polishing pad 16 come into sliding contact with each other. Thus, the work W can be polished. The polishing pad 16 is formed by a polyurethane sheet, a nonwoven fabric sheet impregnated with polyurethane, or the like for example, but is not limited to these.

The arrangement of the polishing head 12 and the platen 14 will be described. While the arrangement of the polishing head 12 and the platen 14 in the work polishing apparatus 10 of the present application is not limited in any way and the numbers of the polishing head 12 and the platen 14 is also not limited, the following arrangement may be employed for example.

FIG. 4 is an explanatory diagram illustrating an example of the arrangement of the polishing head 12, and is a schematic view (plan view) illustrating an example of the work polishing apparatus 10 according to the present embodiment. The work polishing apparatus 10 according to the present embodiment has, on the upper surface of a base body 98, a temporary stand 100 where the work W is attached and detached (loaded and unloaded), and a plurality of (three in the present embodiment) platens 14 radially arranged. On the other hand, above the base body 98, a plurality of (four in the present embodiment) polishing heads 12 with the respective head shafts 18 independently and vertically movably and rotatably supported by and suspended from the support member 102 (the support box 90 and the base frame 74 described above), are radially arranged with an axis 102a matching those of the temporary stand 100 and each platen 14. The support member 102 includes a rotational driving mechanism (not illustrated), and is configured to be rotatable about the axis 102a (including intermittently rotatable in opposite directions). With this configuration, by rotating the support member 102, the polishing heads 12 can orbit about the axis 102a (including intermittently orbiting in opposite directions).

Thus, the polishing head 12 on the temporary stand 100 can be moved sequentially onto each platen 14 by rotating the support member 102. As a result, a series of polishing processes can be performed including: holding and picking up (loading) the work W placed on the temporary stand 100 with the polishing head 12; moving the work W sequentially onto each platen 14 where predetermined polishing (rough polishing, intermediate polishing, and finish polishing for example) is performed; and then returning to the temporary stand 100 onto which the work W polished is placed (unloading). The direction and order of the movement (rotation) of the polishing head 12 in the processes are not limited in any way. The numbers of the platens 14 and the polishing heads 12 are not limited, and the number of the platens 14 and the number of the polishing heads 12 need not be the same. On the temporary stand 100, a loading station and an unloading station where the loading and the unloading respectively take place may be separately provided.

(Work Polishing Method)

Next, a work polishing method according to the present embodiment will be described. The work polishing method according to the present embodiment will be described as a method of using the work polishing apparatus 10 according to the present embodiment for example. Specifically, when the work polishing apparatus 10 according to the present embodiment is applied to the work polishing method according to the present embodiment, the work polishing method according to the present embodiment is a work polishing method including: holding the work W on the lower surface of the holding member provided in a lower portion of the polishing head 12 as illustrated in FIG. 1; lowering the polishing head 12 rotating; and pressing, from the above, the work W onto the polishing pad 16 attached to the upper surface of the rotating platen 14, to polish the work W. The holding member corresponds to the sheet body 34 in the work polishing apparatus 10 according to the present embodiment.

The work polishing method according to the present embodiment further includes: providing the pressing mechanism portion 36 that is vertically movable and can be lowered to press the sheet body 34, on the upper surface side of the sheet body 34; and forming the first fluid chamber 50 on the inner circumference side of the pressing mechanism portion 36 and forming the second fluid chamber 56 on the outer circumference side of the pressing mechanism portion 36. By controlling the internal pressure of the first fluid chamber 50, the pressure applied to the relatively center portion side region of the work W or the entire region (region indicated by the arrow A) of the work W is controlled. By controlling the internal pressure of the second fluid chamber 56, the pressure applied to the relatively circumferential edge portion region of the work W, the outer side region of the work W, or the region (region indicated by the arrow B) covering both of these regions is controlled. Furthermore, by controlling the pressing force of the pressing mechanism portion 36, the pressing force applied to the region (region indicated by the arrow C) corresponding to the lower surface of the pressing mechanism portion 36, positioned between the pressure control region (the region indicated by the arrow A) controlled under the first fluid chamber 50 and the pressure control region (the region indicated by the arrow B) controlled under the second fluid chamber 56 is controlled. Thus, a feature is achieved that these regions indicated by the arrows A, B, and C are each independently controlled.

Thus, the pressures applied to the relatively center portion side region of the work W or the entire region of the work W (the region indicated by the arrow A), the regions corresponding to the pressure control region controlled under the first fluid chamber 50, the relatively circumferential edge portion side region of the work W, the outer side region of the work W, or the region (the region indicated by the arrow B) covering both of these regions, the regions corresponding to the pressure control region controlled under the second fluid chamber 56, and the region that is positioned between these regions and is a region of the work W, the outer side region of the work W, or the region (the region indicated by the arrow C) covering both of these regions, the regions corresponding to the pressing force control region of the pressing mechanism portion 36, can each be independently controlled. As a result, the work W can be polished into a desired thickness shape for an intended purpose.

The work polishing method according to the present embodiment is not limited to the method of using the work polishing apparatus 10 according to the present embodiment. In addition to the work polishing apparatus 10 according to the embodiment of the present invention described above, the work polishing method according to the present embodiment can be applied to a work polishing apparatus 110 according to another embodiment of the present invention including a polishing head 112 illustrated in FIG. 5 for example. The polishing head 112 illustrated in FIG. 5 has a first head member 116 and a second head member 118 provided in a nested manner. A head shaft 114, provided to be vertically movable and rotatable, is fixed to the upper surface center portion of the first head member 116. The second head member 118 is vertically movably suspended from the first head member 116 via a suspending member 120 that is similar to the first, the second, the third, and the fourth suspending members 24, 26, 38, and 40. On the lower side of the second head member 118, a holding member 122 that holds the work W on its lower surface has a circumferential edge portion 122a fixed to the first head member 116.

In the polishing head 112 positioned on the upper surface side of the holding member 122, a pressure adjustable sixth fluid chamber 126, like the first fluid chamber 50, is provided on the inner circumference side of the second head member 118 while being surrounded by the inner wall surface of the second head member 118. On the other hand, a pressure adjustable seventh fluid chamber 128, like the second fluid chamber 56, is provided on the outer circumference side of the second head member 118, between the outer circumference surface of the second head member 118 and the inner circumference surface of the first head member 116 (and the suspending member 120). Furthermore, a pressure adjustable fifth fluid chamber 124, like the third fluid chamber 44, is provided between the lower surface of the first head member 116 and the upper surface of the second head member 118 (and the suspending member 120).

Thus, in the work polishing apparatus 110, the first head member 116 corresponds to a head base portion in claims, the sixth fluid chamber 126 corresponds to a first fluid chamber in claims, the seventh fluid chamber 128 corresponds to a second fluid chamber in claims, and the fifth fluid chamber 124 corresponds to a third fluid chamber in claims. The second head member 118 corresponds to a partitioning portion that can be vertically moved through adjustment of the internal pressure of the fifth fluid chamber 124, and is lowered to partition the sixth and the seventh fluid chambers 126 and 128 formed on the inner and the outer circumference sides thereof so that a pressure difference can be produced between the fluid chambers 126 and 128, and also corresponds to a pressing mechanism portion that can press, via the holding member 122, a region corresponding to the lower surface of the partitioning portion, in a region including the work W and the outer side region of the work W.

When the work polishing apparatus 110 according to the alternative embodiment of the present invention illustrated in FIG. 5 is applied to the work polishing method according to the present embodiment, the second head member 118 that is vertically movable and can be lowered to press the holding member 122 is provided on the upper surface side of the holding member 122, the sixth fluid chamber 126 is formed on the inner circumference side of the second head member 118, and the seventh fluid chamber 128 is formed on the outer circumference side of the second head member 118. By controlling the internal pressure of the sixth fluid chamber 126, the pressure applied to the relatively center portion side of the work W or the entire region of the work W (region indicated by an arrow D) is controlled. By controlling the internal pressure of the seventh fluid chamber 128, the pressure applied to the relatively circumferential edge portion side region of the work W, the outer side region of the work W, or the region (region indicated by an arrow E) covering both of these regions is controlled. By controlling the pressing force of the second head member 118, the pressing force applied to the region (region indicated by an arrow F) corresponding to the lower surface of the second head member 118 positioned between the pressure control region (the region indicated by the arrow D) controlled under the sixth fluid chamber 126 and the pressure control region (the region indicated by the arrow E) controlled under the seventh fluid chamber 128 is controlled. Thus, a feature is achieved that these regions respectively indicated by the arrow D, the arrow E, and the arrow F are each independently controlled.

This makes it possible to independently control pressure applied to each of the relatively center portion side region of the work W or the entire region (the region indicated by the arrow D) of the work W, the regions corresponding to the pressure control region controlled under the sixth fluid chamber 126, the relatively circumferential edge portion side region of the work W, the outer side region of the work W, or the region (the region indicated by the arrow E) covering both of these regions, the regions corresponding to the pressure control region controlled under the seventh fluid chamber 128, and the region that is positioned between these regions and is a region of the work W, the outer side region of the work W, or the region (the region indicated by the arrow F) covering both of these regions, the regions corresponding to the pressing force control region of the second head member 118. As a result, the work W can be polished into a desired thickness shape for an intended purpose.

Next, an example is described where a circular work W is pressed with the work polishing apparatus 10 according to the present embodiment illustrated in FIG. 1 applied to the work polishing method according to the present embodiment. The polishing was performed under the following polishing conditions. Specifically, the polishing pad 16 in the outer side region of the work W was pressed by the retainer ring 22c with the interior of the fourth fluid chamber 28 pressurized to a constant pressure. The polishing head 12 was lowered to a predetermined height position, to mechanically press the region c (region indicated by the arrow C) using the pressing mechanism portion 36. The interior of the first fluid chamber 50 was pressurized at a constant pressure, to achieve a state where the region a (region indicated by the arrow A) was pressed by the pressure of the fluid. With these conditions in common, for the region b (region indicated by the arrow B), the corresponding region covering the work W and the outer side region of the work W was polished with a load applied thereto, with the second flow path 58 negatively pressurized stepwise in a unit of 10 kPa from the state of being opened to the atmosphere.

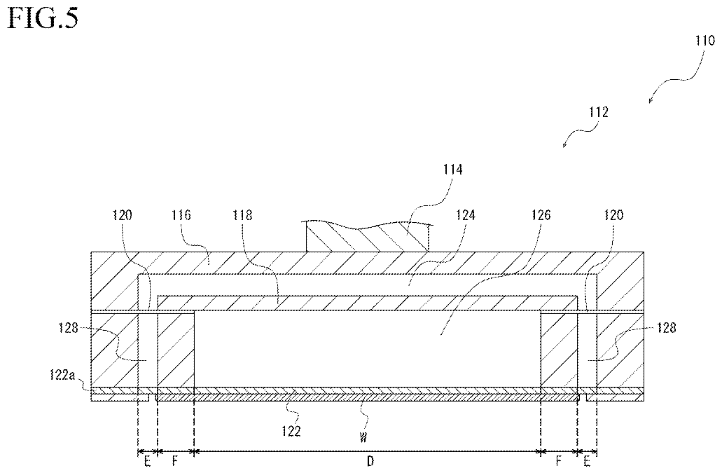

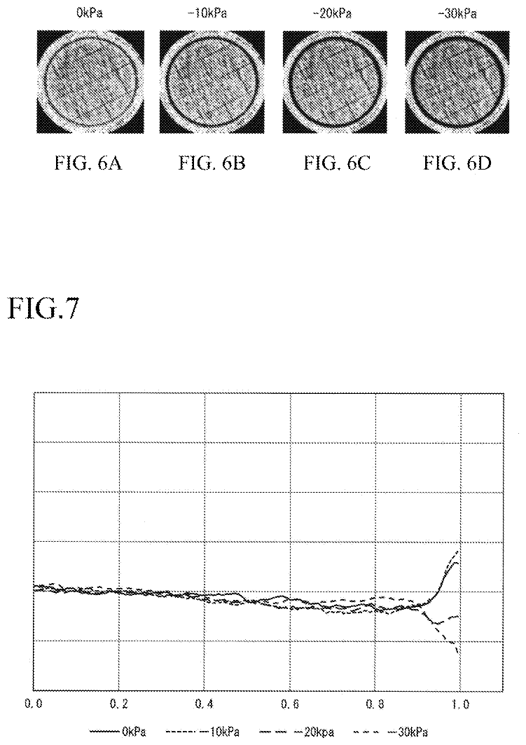

FIGS. 6A-6D are photographs illustrating a load distribution. While transition of color from blue to red indicates an increase in load, in the drawing sheet, a lighter color (closer to the background) indicates a larger load. FIG. 6A illustrates a state where the internal pressure of the second fluid chamber 56 is the atmospheric pressure, due to the second flow path 58 being open to the atmosphere. FIG. 6B illustrates a state where the internal pressure of the second fluid chamber 56 is a negative pressure that is the atmospheric pressure −10 kPa. FIG. 6C illustrates a state where the internal pressure of the second fluid chamber 56 is a negative pressure that is the atmospheric pressure −20 kPa. FIG. 6D illustrates a state where the internal pressure of the second fluid chamber 56 is a negative pressure that is the atmospheric pressure −30 kPa. As illustrated in FIGS. 6A— 6D, it can be understood that only the load on the circumferential edge portion of the work W is reduced through the stepwise negative pressurization in the second fluid chamber 56. Thus, the pressing force applied to a predetermined region of the work W could be independently controlled without affecting the other regions.

FIG. 7 is a graph illustrating a polishing amount. The horizontal axis represents the radius of the circular work W that is converted to be illustrated, to be 0 at the center point and 1.0 at the outer circumference point. On the vertical axis, which represents the polishing amount, the unit and the scale values are omitted, since it suffices if relative changes can be recognized. As illustrated in FIG. 7, the polishing amount of the work W substantially horizontally transitions as a whole from the center portion toward the outer circumference portion. Thus, it can be understood that the polishing amount in a region of the work W excluding the circumferential edge portion can be uniformized, by setting the same predetermined pressure for the region a and the region c. On the other hand, in the circumferential edge portion of the work W, the polishing amount constantly increased toward the outer circumference portion while the interior of the second fluid chamber 56 was in the atmospheric pressure and in the −10 kPa negative pressure state, whereas the polishing amount extremely gradually and constantly decreased toward the outer circumference portion without inflection in the −20 kPa negative pressure state. On the other hand, in the −30 kPa negative pressure state, the polishing amount largely and constantly decreased toward the outer circumference portion. Thus, it can be understood that by adjusting the internal pressure of the second fluid chamber 56 corresponding to the region b, only the polishing amount in the circumferential edge portion can be changed, without largely changing the polishing amount of the work W as a whole. Thus, by changing the pressing force applied to the predetermined region of the work W, the polishing amount of the predetermined region could be changed. Thus, by adjusting the ranges of and the pressing force on the region a, the region b, and the region c, the polishing amount and the inflection point of the work W in the radial direction can be adjusted in any way, whereby the work W can be polished into a desired thickness shape for an intended purpose.

What is claimed is:

1. A work polishing apparatus comprising:
a platen having an upper surface on which a polishing pad is attached, the platen rotating in a horizontal plane; and
a polishing head that is above the platen, and includes a head base portion in an upper portion and a holding member in a lower portion, in which a head shaft that is vertically movable and rotatable is fixed and provided on an upper surface of the head base portion, a work is configured to be held on a lower surface of the holding member, and the work is configured to be lowered while rotating, via the head shaft, to be pressed, from above, onto the polishing pad on the upper surface of the platen rotating to be polished, wherein
the polishing head is provided with a first fluid chamber on side of an upper surface of the holding member, a second fluid chamber more on side of outer circumference than the first fluid chamber, and a partitioning portion that is vertically movable and is provided between the first fluid chamber and the second fluid chamber,
a fluid is capable of being supplied into and discharged from each of the first fluid chamber and the second fluid chamber independently, pressure in the first fluid chamber and pressure in the second fluid chamber are each capable of being independently increased and decreased, and
the partitioning portion is configured to be capable of being lowered at least to a position where the first fluid chamber and the second fluid chamber are partitioned in such a manner that a pressure difference is capable of being produced between the interior of the first fluid chamber and the interior of the second fluid chamber.

2. The work polishing apparatus according to claim 1, wherein
the partitioning portion is coupled to the head base portion and vertically moves together with the head base portion vertically moving via the head shaft, or
the partitioning portion is vertically movably suspended from the head base portion, and
a third fluid chamber into and from which the fluid is capable of being supplied and discharged is further provided above the partitioning portion, and the partitioning portion vertically moves in response to an increase or decrease in pressure in the third fluid chamber.

3. The work polishing apparatus according to claim 1, wherein the partitioning portion is a pressing mechanism portion capable of pressing a region, in a region including the work and an outer side region of the work, corresponding to a lower surface of the partitioning portion, via the holding member, by being lowered to press the holding member.

4. The work polishing apparatus according to claim 3, wherein a pressing member is detachably attached to a lower surface of the pressing mechanism portion or in a region of the upper surface of the holding member corresponding to the lower surface of the pressing mechanism portion.

5. The work polishing apparatus according to claim 4, wherein the pressing member is detachably attached to the lower surface of the pressing mechanism portion via an attachment.

6. The work polishing apparatus according to claim 2, wherein
in the polishing head,
the head base portion includes a base top plate having the head shaft fixed to an upper surface center portion, and a shaft portion protruding in a lower surface center portion of the base top plate,
a work guide is positioned below the head base portion to be vertically movable with respect to the head base portion via a first suspending member,
the partitioning portion is positioned below the work guide, is vertically movably suspended from the work guide via a second suspending member on outer circumference side, and is coupled to the shaft portion or is suspended via a third suspending member on inner circumference side,
a holding plate is provided to a lower end of the shaft portion,
the holding member is a sheet body that is provided to be positioned below the holding plate and has a circumferential edge portion fixed to the work guide,
the first fluid chamber is formed between an upper surface of the sheet body and a lower surface of the holding plate on the inner circumference side of the partitioning portion, and
the second fluid chamber is formed between an outer circumference surface of the partitioning portion and an inner circumference surface of the work guide on the outer circumference side of the partitioning portion.

7. The work polishing apparatus according to claim 3, wherein
in the polishing head,
the head base portion includes a base top plate having the head shaft fixed to an upper surface center portion, and a shaft portion protruding in a lower surface center portion of the base top plate,
a work guide is positioned below the head base portion to be vertically movable with respect to the head base portion via a first suspending member,
the partitioning portion is positioned below the work guide, is vertically movably suspended from the work guide via a second suspending member on outer circumference side, and is coupled to the shaft portion or is suspended via a third suspending member on inner circumference side,
a holding plate is provided to a lower end of the shaft portion,
the holding member is a sheet body that is provided to be positioned below the holding plate and has a circumferential edge portion fixed to the work guide,
the first fluid chamber is formed between an upper surface of the sheet body and a lower surface of the holding plate on the inner circumference side of the partitioning portion, and
the second fluid chamber is formed between an outer circumference surface of the partitioning portion and an inner circumference surface of the work guide on the outer circumference side of the partitioning portion.

8. A work polishing method of polishing, into a set thickness shape, a work held on a lower surface of a holding member provided in a lower portion of a polishing head, by rotating and lowering the polishing head, and pressing, from above, the work onto a polishing pad attached to an upper surface of a platen rotating, with a pressing mechanism portion that is vertically movable and capable of being lowered to press the holding member provided on side of an upper surface of the holding member, and with a first fluid chamber and a second fluid chamber respectively provided on inner circumference side and outer circumference side of the pressing mechanism, the work polishing method comprising:
controlling pressure in the first fluid chamber to control pressure applied to a relatively center portion side region of the work or to an entire region of the work, the regions corresponding to the first fluid chamber;
controlling pressure in the second fluid chamber to control pressure applied to a relatively circumferential edge portion side region of the work, to an outer side region of the work, or to a region covering both of the relatively circumferential edge portion side region of the work and the outer side region of the work, the regions corresponding to the second fluid chamber; and
controlling pressing force of the pressing mechanism portion to control pressing force applied to a region corresponding to a lower surface of the pressing mechanism portion positioned between a pressure control region controlled under the first fluid chamber and a pressure control region controlled under the second fluid chamber.
